(19) United States
(12) Patent Application Publication
(10) Pub. No.: US 2026/0003251 A1
(43) Pub. Date: Jan. 1, 2026

(54) Camera Device with Heating Module

(71) Applicant: WHETRON ELECTRONICS CO., LTD., New Taipei City (TW)

(72) Inventor: Chien-Hung TU, New Taipei City (TW)

(21) Appl. No.: 18/797,556

(22) Filed: Aug. 8, 2024

(30) Foreign Application Priority Data
Jun. 26, 2024 (TW) 113123823

(51) Int. Cl. G03B 17/55; G02B 7/02; H01R 12/78; H05K 1/18

(52) U.S. Cl. CPC G03B 17/55; G02B 7/021; H01R 12/78; H05K 1/181; H05K 2201/10121; H05K 2201/10151; H05K 2201/10189

(57) ABSTRACT

A camera device with heating module includes a first housing, a plurality of lenses, a heating module, a second housing and a circuit board. The first housing includes a first channel and a second channel. The plurality of lenses is arranged in the first channel. The heating module includes a heating unit and a connection unit. The heating unit is arranged at a specific position of the plurality of lenses. The connection unit is connected to the heating unit and disposed within and extending along the second channel. The second housing is coupled with the first housing to form an accommodation space. The circuit board is disposed in the accommodation space. The connection unit is electrically connected to the circuit board.

### CROSS REFERENCE TO RELATED APPLICATION

The application claims the benefit of Taiwan Application Serial No. 113123823, filed on Jun. 26, 2024, and the entire contents of which are incorporated herein by reference.

### BACKGROUND OF THE INVENTION

### 1. Field of the Invention

The present invention relates to a camera device and, more particularly, to a camera device with a heating module.

### 2. Description of the Related Art

In the commonly known camera device 9, the camera device 9 includes a first housing 91 and a second housing 92 coupled with the first housing 91. An accommodation space is defined between the first housing 91 and the second housing 92 to accommodate at least one circuit board 93 in the accommodation space. The first housing 91 further includes a front cover 911, a front lens 912 and a lens module 913 disposed in the first housing 91. The lens module 913 includes a plurality of lenses to achieve the image capturing function of the camera device 9.

In order to avoid or eliminate situations such as freezing/frosting or moisture on the front lens 912 and the plurality of lenses in the lens module 913, a heating module 94 is further provided to be arranged between the front lens 912 and the lens module 913. In order to maintain the heating module 94 at a specific position, a support member 95 is further provided to support the heating module 94 in the accommodation space formed by the first housing 91 and the second housing 92 after coupling. Particularly, one end of the support member 95 rests on at least one circuit board 93, and the other end of the support member 95 is used to support the heating module 94.

In detail, the heating module 94 includes a connection element 94C. One free end of the connection element 94C is provided with a first electrical connector 94P. The at least one circuit board 93 includes a second electrical connector 93P. With the electrical connection between the first electrical connector 94P and the second electrical connector 93P, electrical power required for the heating module 94 to generate heat can be provided.

However, during the assembly of components of the known camera device 9, the connection element 94C made entirely of flexible wires allows the first electrical connector 94P located at the free end to move freely to a certain degree. As a result, when connecting the first electrical connector 94P and the second electrical connector 93P, the alignment is difficult due to the movement of the first electrical connector 94P, and interference or collision of the first electrical connector 94P with other components is likely to occur. Therefore, additional manual effort is required to assemble, leading to assembly inconvenience and increased costs.

In view of this, it is necessary to improve the known camera device.

### SUMMARY OF THE INVENTION

To solve the above problems, an objective of the present invention is to provide a camera device with heating module, which can avoid the collision of the connection unit with other components or structures during assembly process, thereby enhancing the assembly convenience.

As used herein, the term “a”, “an” or “one” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

As used herein, the term “engagement”, “coupling”, “assembly”, or similar terms is used to include separation of connected members without destroying the members after connection or inseparable connection of the members after connection. A person having ordinary skill in the art would be able to select according to desired demands in the material or assembly of the members to be connected.

A camera device with heating module according to the present invention includes a first housing, a plurality of lenses, a heating module, a second housing and a circuit board. The first housing has a first end and a second end and includes a first channel and a second channel. The first channel connects the first end and the second end. The second channel connects a side of the first end and a side of the second end. The plurality of lenses is arranged in the first channel. The heating module includes a heating unit and a connection unit. The heating unit is arranged at a specific position of the plurality of lenses. The connection unit is connected to the heating unit and disposed within and extending along the second channel. The second housing is coupled with the first housing to form an accommodation space. The circuit board is disposed in the accommodation space. The connection unit disposed within and extending along the second channel is electrically connected to the circuit board.

Therefore, in the camera device with heating module of the present invention, the heating module/the heating unit is directly supported by the first housing, thus eliminating the needs to provide an additional component for support, thereby enhancing assembly convenience and reducing the cost of manufacturing the additional component. Furthermore, the second channel can be used exclusively for placing the connection unit, thus avoiding the collision of the connection unit with other components or structures during assembly process, thereby enhancing assembly convenience.

In an example, the plurality of lenses includes a first lens which is farthest away from the circuit board. The heating unit is arranged between the first lens and the circuit board. Thus, with the configuration of the heating unit, the effect of avoiding or removing frost or moisture on the plurality of lenses can be achieved.

In an example, the plurality of lenses further includes a second lens arranged between the first lens and the circuit board. The heating unit is arranged between the first lens and the second lens. Thus, the effect of avoiding or removing frost or moisture on the plurality of lenses more efficiently can be achieved.

In an example, the first housing includes a first sub-housing and a second sub-housing. The first sub-housing and the second sub-housing are each provided with at least one of the plurality of lenses. Thus, with the structural configuration of the first sub-housing and the second sub-housing, the first housing can be provided with lenses in one of the first and second sub-housing according to actual demand, thereby enhancing assembly convenience.

In an example, the connection unit includes a first connection part protruding from the second channel and arranged on a wall of the first housing near the second end. The circuit board includes a second connection part connected to the first connection part. Thus, with the positional configuration of the first and second connection part, during the assembly of the first housing and the second housing, the collision of the first and second connection part with other components or structures can be avoided, thereby enhancing assembly convenience.

In an example, the first connection part is a gold finger connecter, and the second connection part is a flexible probe. Thus, the effect of enhancing assembly convenience can be achieved.

In an example, the circuit board includes a plurality of sub-circuit boards electrically connected with each other. Thus, with the circuit board including multiple sub-circuit boards, the problem of increased manufacturing costs due to the needs for more precise circuit layout on a single circuit board can be avoided.

In an example, one of the plurality of sub-circuit boards includes an image sensor. Thus, with the image sensor, the optical information obtained by the plurality of lenses can be received and/or converted.

In an example, the image sensor and the second connection part are provided on the same sub-circuit board of the plurality of sub-circuit boards. Thus, by arranging the image sensor and the second connection part on the same sub-circuit board, other sub-circuit boards can have more space for the arrangement of circuits or components for other functions.

In an example, the image sensor and the second connection part are provided on different sub-circuit boards of the plurality of sub-circuit boards. Thus, by arranging the image sensor and the second connection part on different sub-circuit boards, the problem of increased manufacturing costs due to the needs for more precise circuit layout on a single circuit board can be avoided.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is an exploded perspective view of the known camera device with heating module.

FIG. 2 is a partial exploded perspective view of the first preferred embodiment of the present invention.

FIG. 3 is an exploded perspective view of components arranged in the first housing as shown in FIG. 2.

FIG. 4 is a cross-sectional view of the first preferred embodiment of the present invention.

FIG. 5 is a partial exploded perspective view of the second preferred embodiment of the present invention.

FIG. 6 is a cross-sectional view of the second preferred embodiment of the present invention.

When the terms “front”, “rear”, “left”, “right”, “up”, “down”, “top”, “bottom”, “inner”, “outer”, “side”, and similar terms are used herein, it should be understood that these terms have reference only to the structure shown in the drawings as it would appear to a person viewing the drawings and are utilized only to facilitate describing the invention, rather than restricting the invention.

### DETAILED DESCRIPTION OF THE INVENTION

In order to make the above and other objectives, features, and advantages of the present invention clearer and easier to understand, the preferred embodiments of the present invention will be described hereinafter in connection with the accompanying drawings. Furthermore, the elements designated by the same reference numeral in various figures will be deemed as identical, and the description thereof will be omitted.

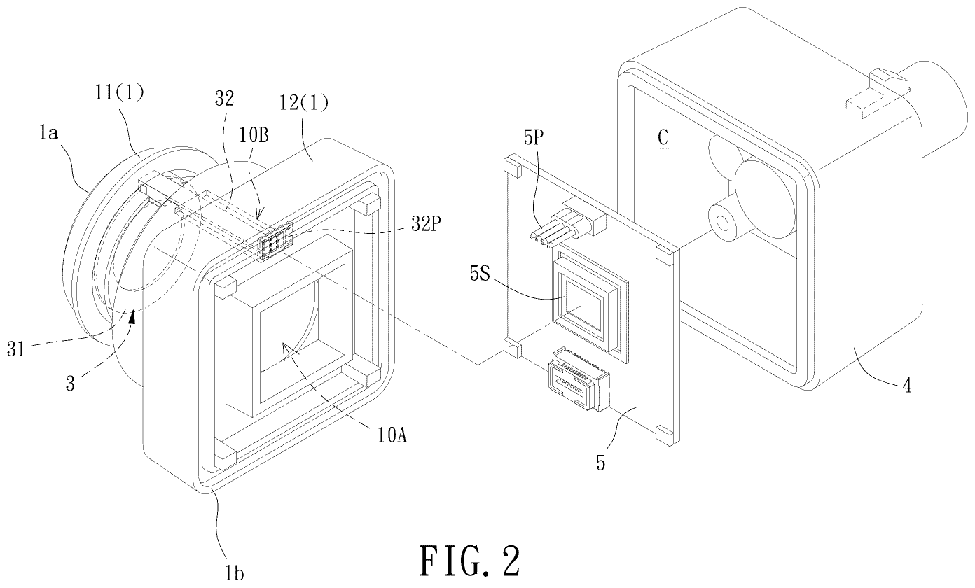

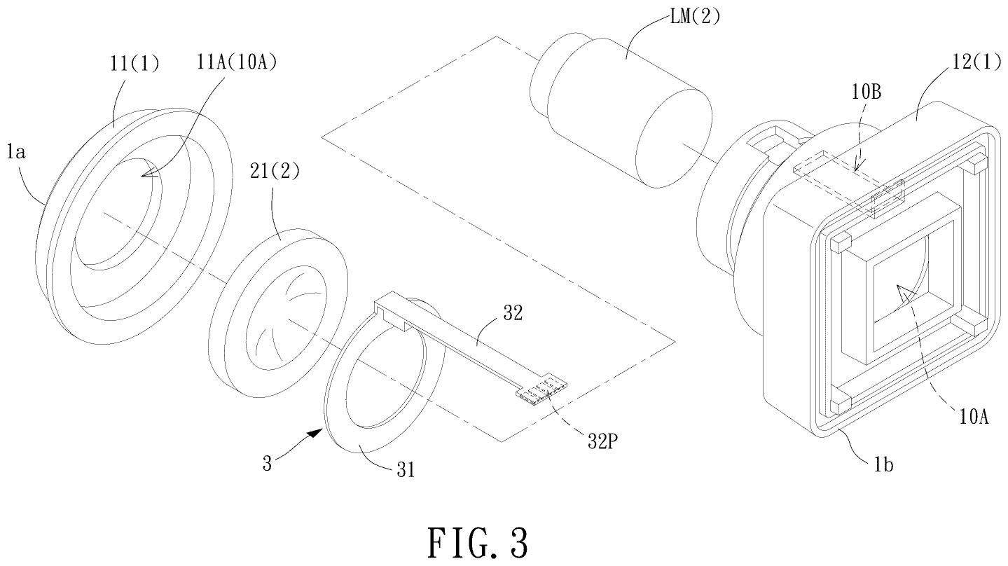

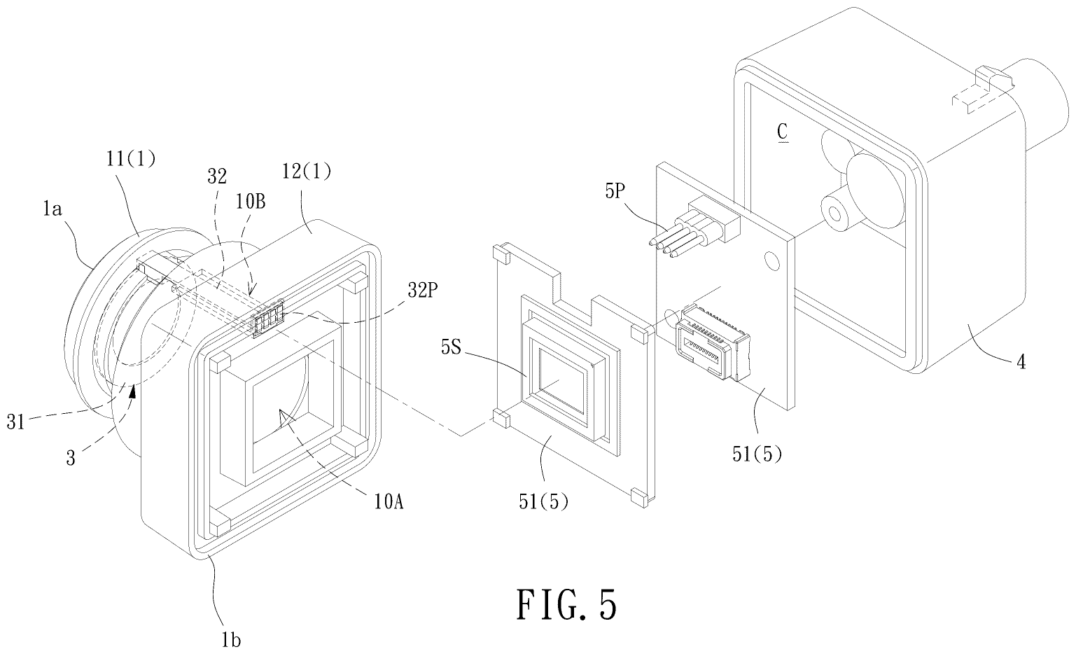

With reference to FIGS. 2-5, which is a first preferred embodiment of the camera device with heating module of the present invention, the camera device with heating module includes a first housing 1, a plurality of lenses 2, a heating module 3, a second housing 4 and a circuit board 5. The plurality of lenses 2 and the heating module 3 are arranged in the first housing 1. The first housing 1 is coupled with the second housing 4 to define an accommodation space S. The circuit board 5 is disposed in the accommodation space S.

As shown in FIGS. 2, 3 and 5, the first housing 1 has a first end 1a and a second end 1b. The first end 1a and the second end 1b are opposite to each other in an axial direction. The first housing 1 includes a first channel 10A (particularly extending along the axial direction) connecting the first end 1a and the second end 1b. Particularly, the first channel 10A is formed by a wall of the first housing 1. Optionally, the first housing 1 further includes a second channel 10B (particularly extending along the axial direction) connecting a side of the first end 1a and a side of the second end 1b. Particularly, the second channel 10B is formed by a wall of the first housing 1. Preferably, the second channel 10B and the first channel 10A are separate and independent channels which are not connected to each other. However, it should be noted that in some embodiments, a configuration in which the first channel 10A and the second channel 10B are partially connected is not excluded. Optionally, the first housing 1 includes a first sub-housing 11 and a second sub-housing 12. The first sub-housing 11 has a first sub-channel 11A. The second sub-housing 12 has a second sub-channel 12A. When the first sub-housing 11 and the second sub-housing 12 are coupled, the first sub-channel 11A and the second sub-channel 12A are interconnected to form the first channel 10A.

The plurality of lenses 2 is arranged in the first housing 1, particularly in the first channel 10A. The plurality of lenses 2 includes a first lens 21 which is farthest away from the circuit board 5. Particularly, the first lens 21 of the plurality of lenses 2 is farthest away from the second end 1b of the first housing 1. In other words, the first lens 21 is farthest away from the circuit board 5. In addition, the plurality of lenses 2 further includes a second lens (not shown in the drawings). Particularly, the other lenses of the plurality of lenses 2 excluding the first lens 21 are arranged in a lens module LM, and the second lens is arranged in the lens module LM. That is, the second lens/the lens module LM is arranged between the first lens 21 and the circuit board 5. Optionally, the first sub-housing 11 and the second sub-housing 12 are each provided with at least one of the plurality of lenses 2. For example, the first lens 21 may be arranged in the first sub-housing 11, and the second lens/the lens module LM may be arranged in the second sub-housing 12. It should be noted that the technique of arranging at least one lens in the lens module LM (i.e., the lens module LM at least includes the second lens) is understood by a person skilled in the art, and the description thereof will be omitted.

The heating module 3 is arranged in the first housing 1. The heating module 3 includes a heating unit 31 and a connection unit 32. The heating unit 31 may be used to generate heat to avoid or eliminate situations such as freezing/frosting or moisture on the plurality of lenses 2. The heating unit 31 is positioned at a specific position of the plurality of lenses 2. Particularly, the heating unit 31 may surround one or more of the plurality of lenses 2 at the specific position. Optionally, the heating unit 31 is arranged between the first lens 21 and the circuit board 5. Preferably, the heating unit 31 is arranged between the first lens 21 and the second lens/the lens module LM. Thus, it can be more efficient to avoid or eliminate situations such as freezing/frosting or moisture on the first lens 21. Optionally, the heating unit 31 is formed in a ring shape.

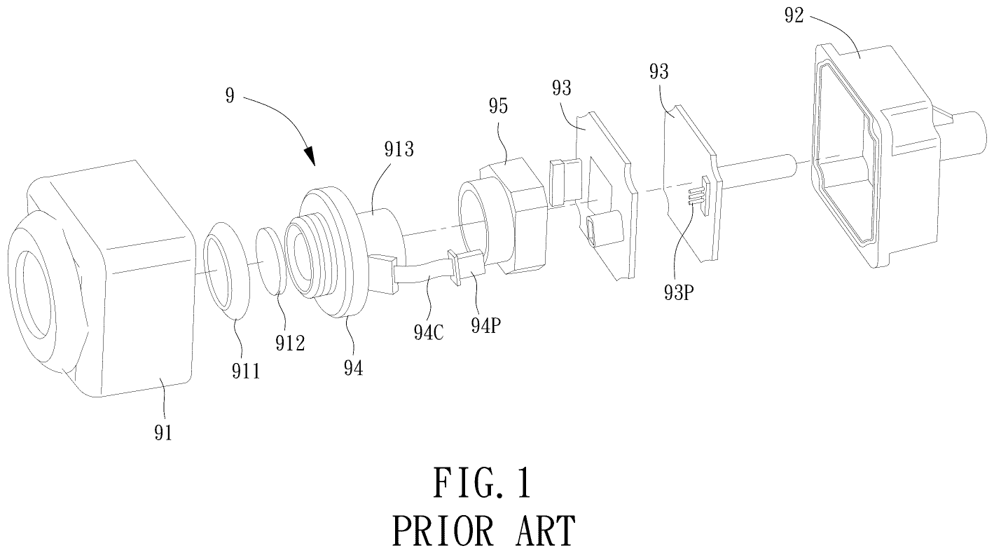

It should be noted that, in the known camera device 9 as shown in FIG. 1, in order to arrange the heating module 94 at a target position of the lens module 913 in the accommodation space formed by the first housing 91 and the second housing 92, a support member 95 must be additionally provided to support the heating module 94 to be arranged at the target position. Particularly, in order to place the support member 95, the at least one circuit board 93 may require corresponding fitting structures or increased strength for the support member 95 to abut against. Therefore, in the known camera device 9, the additional support member 95 is required to support the heating module 94, resulting in a larger number of overall components of the known camera device 9 and increased assembly complexity. In this regard, in an optional embodiment of the present invention, the heating module 3 can be assembled from the first end 1a of the first housing 1, and the heating module 3/the heating unit 31 can be directly supported by the first housing 1, so as to eliminate the needs to provide an additional component (such as the support member 95) for support as in the known camera device 9 (as shown in FIG. 1), thereby enhancing the assembly convenience and reducing the cost of manufacturing the additional supporting component.

The connection unit 32 is connected to the heating unit 31. The connection unit 32 can be used to transmit electrical power required for the heating unit 31 to generate heat. The connection unit 32 is disposed within and extending along the second channel 10B. Particularly, the connection unit 32 extends from the heating unit 31 (along an axial direction). Thus, the second channel 10B can be used exclusively for placing the connection unit 32 so that the whole or a major part of the connection unit 32 is positioned within the second channel 10B. Particularly, for example, only ends of the connection unit 32 (one end connected to the heating unit 31 and/or one end [e.g., a first connection part 32P as described later] connected to a second connection part 5P of the circuit board 5 as described later) are exposed outside the second channel 10B, so that the collision of the connection unit 32 with other components or structures can be avoided during assembly process.

Optionally, the connection unit 32 includes a first connection part 32P. Particularly, the first connection part 32P of the connection unit 32 protrudes from the second channel 10B and is arranged on a wall of the first housing 1 near the second end 1b. Particularly, the first connection part 32P may be coupled with the wall of the first housing 1 near the second end 1b described above by means such as adhesion or snap-fit, but is not limited to these coupling means. In an example, the connection unit 32 may be a flexible circuit board, and the first connection part 32P may be a gold finger connecter; in another example, the first connection part 32P may be an electrical slot. However, the present invention is not limited to these examples.

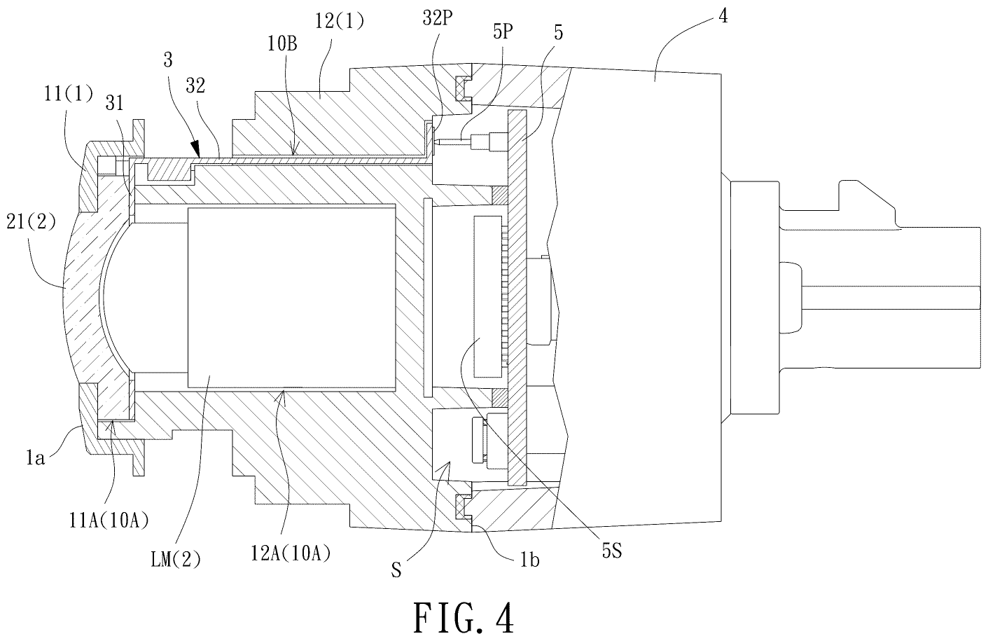

As shown in FIGS. 2, 4 and 5, the second housing 4 is coupled with the first housing 1 to jointly define an accommodation space S (as shown in FIG. 4). In detail, at least one of the first housing 1 and the second housing 4 has a corresponding recessed part C. When the first housing 1 and the second housing 4 are coupled, the corresponding recessed part C forms the accommodation space S. In the illustrated examples of the present invention, although the second housing 4 is described as having the recessed part C, the configuration of the recessed part C can be modified according to the needs and is not limited to the drawings disclosed in the present invention.

The circuit board 5 is disposed within the accommodation space S. The connection unit 32 is electrically connected to the circuit board 5 to transmit electrical power from the circuit board 5 through the connection unit 32 to the heating unit 31. In detail, the circuit board 5 includes a second connection part 5P and may further include an image sensor 5S. Particularly, the second connection part 5P and the image sensor 5S are provided on the circuit board 5 facing the second end 1b. The second connection part 5P is connected to the first connection part 32P, particularly electrically connected. The image sensor 5S is used to receive optical information obtained by the plurality of lenses 2. In an example, the second connection part 5P may be a probe, preferably a flexible probe such as a spring probe (pogo pin) to better match the configuration of the first connection part 32P as a gold finger connecter. In another example, the second connection part 5P may be a pin header to better match the configuration of the first connection part 32P as an electrical slot. However, the present invention is not limited to these examples.

It should be noted that in an example, before assembling the first housing 1 and the second housing 4, the first connection part 32P is arranged on the wall of the first housing 1 near the second end 1b, establishing a first specific positional relationship between the first connection part 32P and the first housing 1; and the circuit board 5 can be pre-disposed in the recessed part C of the second housing 4, establishing a second specific positional relationship between the second connection part 5P and the second housing 4. With the configuration of the first specific positional relationship and the second specific positional relationship, during the assembly of the first housing 1 and the second housing 4, the first connection part 32P and the second connection part 5P can be aligned. Moreover, during the process from separation to coupling of the first housing 1 and the second housing 4, the first connection part 32P can be configured to only contact the second connection part 5P, and the second connection part 5P can be configured to only contact the first connection part 32P. In other words, during the coupling process of the first housing 1 and the second housing 4, the first connection part 32P and the second connection part 5P will not collide with other components or structures, thereby achieving the effect of convenient assembly.

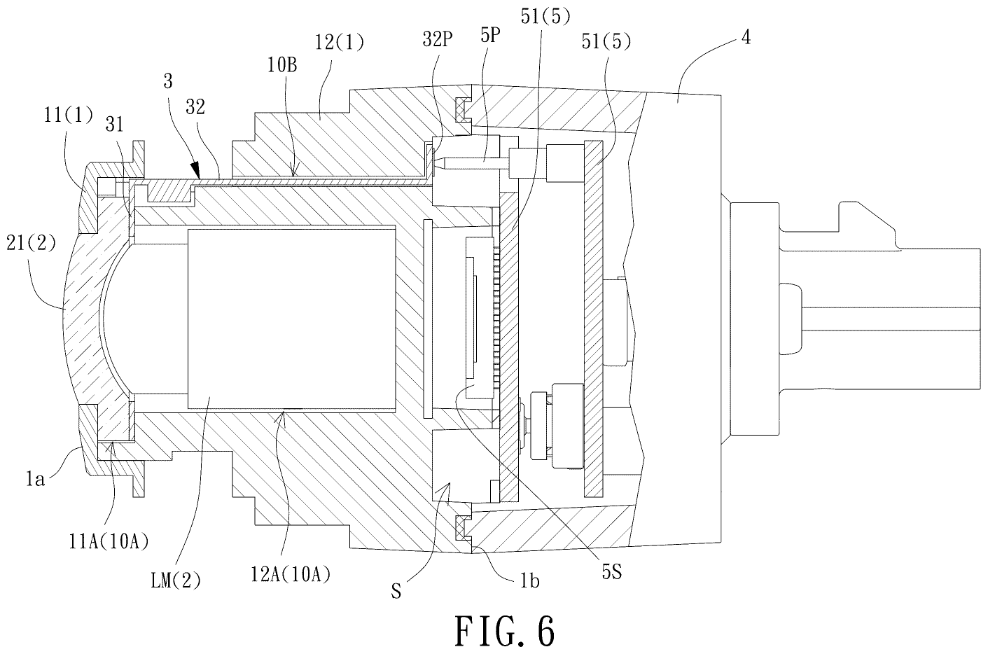

With reference to FIGS. 6 and 7, which is a second preferred embodiment of the camera device with heating module according to the present invention. The second preferred embodiment is substantially the same as the first preferred embodiment, with the main difference being that in the second preferred embodiment, the circuit board 5 can include a plurality of sub-circuit boards 51. The plurality of sub-circuit boards 51 is electrically connected (including direct or indirect electrical connection) with each other. In an example, there are two sub-circuit boards 51, and the second connection part 5P and the image sensor 5S are provided on different sub-circuit boards 51. Particularly, the image sensor 5S is provided on the sub-circuit board 51 close to the lens module LM, and the second connection part 5P is provided on the other sub-circuit board 51 remote from the lens module LM. In another example, the second connection part 5P and the image sensor 5S can be provided on the same sub-circuit board 51. Therefore, it should be noted that the number of the plurality of sub-circuit boards 51 and the configuration of whether the second connection part 5P and the image sensor 5S are provided on the same sub-circuit board 51 are not limited to the drawings disclosed in the present invention.

In view of the forgoing, in the camera device with heating module of the present invention, the heating module/heating unit is directly supported by the first housing, thus eliminating the needs to provide an additional component for support, thereby enhancing assembly convenience and reducing the cost of manufacturing the additional component. The second channel can be used exclusively for placing the connection unit, thus avoiding the collision of the connection unit with other components or structures during assembly process, thereby enhancing assembly convenience. The heating module is arranged between the first lens and the second lens/the lens module, thus avoiding or eliminating situations such as freezing/frosting or moisture on the first lens more efficiently. With the specific positional configuration (i.e., the first and second specific positional relationship) of the first and second connection part, during the assembly of the camera device with heating module of the present invention, the first and second connection part will not collide with other components or structures, thereby enhancing assembly convenience. With the configuration of the first and second connection part as a gold finger connecter and a flexible probe respectively, the effect of convenient assembly can be achieved.

Although the present invention has been described with respect to the above preferred embodiments, these embodiments are not intended to restrict the present invention. Various changes and modifications on the above embodiments made by any person skilled in the art without departing from the spirit and scope of the present invention are still within the technical category protected by the present invention. Accordingly, the scope of the present invention shall include the literal meaning set forth in the appended claims and all changes which come within the range of equivalency of the claims. Furthermore, in a case that several of the above embodiments can be combined, the present invention includes the implementation of any combination.

What is claimed is:

1. A camera device with heating module, comprising:
a first housing having a first end and a second end and including a first channel and a second channel, wherein the first channel connects the first end and the second end, and wherein the second channel connects a side of the first end and a side of the second end;
a plurality of lenses arranged in the first channel;
a heating module including a heating unit and a connection unit, wherein the heating unit is arranged at a specific position of the plurality of lenses, and wherein the connection unit is connected to the heating unit and disposed within and extending along the second channel;
a second housing coupled with the first housing to form an accommodation space; and
a circuit board disposed in the accommodation space;
wherein the connection unit disposed within and extending along the second channel is electrically connected to the circuit board.

2. The camera device with heating module as claimed in claim 1, wherein the plurality of lenses includes a first lens which is farthest away from the circuit board, and wherein the heating unit is arranged between the first lens and the circuit board.

3. The camera device with heating module as claimed in claim 2, wherein the plurality of lenses further includes a second lens arranged between the first lens and the circuit board, and wherein the heating unit is arranged between the first lens and the second lens.

4. The camera device with heating module as claimed in claim 1, wherein the first housing includes a first sub-housing and a second sub-housing, and wherein the first sub-housing and the second sub-housing are each provided with at least one of the plurality of lenses.

5. The camera device with heating module as claimed in claim 1, wherein the connection unit includes a first connection part protruding from the second channel and arranged on a wall of the first housing near the second end, and wherein the circuit board includes a second connection part connected to the first connection part.

6. The camera device with heating module as claimed in claim 5, wherein the first connection part is a gold finger connecter, and the second connection part is a flexible probe.

7. The camera device with heating module as claimed in claim 1, wherein the circuit board includes a plurality of sub-circuit boards electrically connected with each other.

8. The camera device with heating module as claimed in claim 7, wherein one of the plurality of sub-circuit boards includes an image sensor.

9. The camera device with heating module as claimed in claim 8, wherein the image sensor and the second connection part are provided on the same sub-circuit board of the plurality of sub-circuit boards.

10. The camera device with heating module as claimed in claim 8, wherein the image sensor and the second connection part are provided on different sub-circuit boards of the plurality of sub-circuit boards.
